(19) United States
(12) Patent Application Publication
(10) Pub. No.: US 2026/0266728 A1
(43) Pub. Date: Sep. 10, 2026

(54) FLUORESCENCE DETECTION DEVICE

(71) Applicant: Magnolia White Corporation, Tokyo (JP)

(72) Inventor: Masaya ADACHI, Tokyo (JP)

(73) Assignee: Magnolia White Corporation, Tokyo (JP)

(21) Appl. No.: 19/661,868

(22) Filed: Apr. 29, 2026

Related U.S. Application Data
(63) Continuation of application No. PCT/JP2024/035328, filed on Oct. 2, 2024.

(30) Foreign Application Priority Data
Nov. 1, 2023 (JP) 2023-187773

(51) Int. Cl. G01N 21/64

(52) U.S. Cl. CPC G01N 21/6456; G01N 21/6454; G01N 2021/6463

(57) ABSTRACT

According to an aspect, a fluorescence detection device includes: a substrate; a light source configured to output excitation light to a sample; and a detector configured to detect fluorescence. The detector includes: a light guide layer having a light-transmitting property; a through-hole penetrating the light guide layer in a direction perpendicular to the substrate; a light-receiving element covered by the light guide layer and configured to receive fluorescence emitted from the sample due to the excitation light; and a light-reducing layer provided on the light guide layer and configured to reduce transmission of the excitation light. The light-reducing layer has a plurality of openings. A plurality of housing parts each surrounded by a sidewall of the through-hole and configured to accommodate the sample are formed. The openings are formed at positions overlapping the housing parts. The light-receiving element is disposed surrounding each of the housing parts in plan view.

### CROSS-REFERENCE TO RELATED APPLICATION

This application claims the benefit of priority from Japanese Patent Application No. 2023-187773 filed on Nov. 1, 2023 and International Patent Application No. PCT/JP2024/035328 filed on Oct. 2, 2024, the entire contents of which are incorporated herein by reference.

### BACKGROUND

### 1. Technical Field

What is disclosed herein relates to a fluorescence detection device.

### 2. Description of the Related Art

Widely known are detection devices including an optical system with a dichroic mirror and configured to detect fluorescence reflected from a sample (e.g., Japanese Patent Application Laid-open Publication No. 2005-321753 (JP-A-2005-321753)).

The detection device described in JP-A-2005-321753, however, is designed to reflect excitation light using the dichroic mirror to irradiate the sample. This structure requires a larger number of parts, which may increase the overall size of the detection device.

For the foregoing reasons, there is a need for a fluorescence detection device that can be downsized in a simpler manner.

### SUMMARY

According to an aspect, a fluorescence detection device includes: a substrate; a light source configured to output excitation light to a sample; and a detector configured to detect fluorescence. The detector includes: a light guide layer having a first surface and a second surface opposite to the first surface and having a light-transmitting property; a through-hole penetrating the light guide layer from the first surface to the second surface in a direction perpendicular to the substrate; a light-receiving element covered by the light guide layer and configured to receive fluorescence emitted from the sample due to the excitation light; and a light-reducing layer provided on the light guide layer and configured to reduce transmission of the excitation light. The light-reducing layer has a plurality of openings. A plurality of housing parts each surrounded by a sidewall of the through-hole and configured to accommodate the sample are formed. The openings are formed at positions overlapping the housing parts. The light-receiving element is disposed surrounding each of the housing parts in plan view.

### BRIEF DESCRIPTION OF THE DRAWINGS

FIG. 1 is a plan view of a fluorescence detection device according to a first embodiment;

FIG. 2 is a block diagram of an exemplary configuration of the fluorescence detection device according to the first embodiment;

FIG. 3 is a circuit diagram of sensor pixels according to the first embodiment;

FIG. 4 is a plan view of a light guide layer of the fluorescence detection device according to the first embodiment;

FIG. 5 is a plan view of a light-reducing layer of the fluorescence detection device according to the first embodiment;

FIG. 6 is a sectional view along line VI-VI′ of FIG. 4;

FIG. 7 is a sectional view along line VII-VII′ of FIG. 4;

FIG. 8A is a sectional view of the fluorescence detection device according to a first modification of the first embodiment;

FIG. 8B is a sectional view of the fluorescence detection device according to a second modification of the first embodiment;

FIG. 9 is a plan view of the fluorescence detection device according to a second embodiment;

FIG. 10 is a sectional view along line X-X′ of FIG. 9;

FIG. 11 is a plan view of the fluorescence detection device according to a third embodiment;

FIG. 12 is a sectional view along line XII-XII′ of FIG. 11;

FIG. 13 is a plan view of the fluorescence detection device according to a fourth embodiment; and

FIG. 14 is a sectional view along line XIV-XIV′ of FIG. 13.

### DETAILED DESCRIPTION

Exemplary aspects (embodiments) to embody the disclosure are described below in greater detail with reference to the accompanying drawings. The contents described in the embodiments below are not intended to limit the present disclosure. Components described below include components easily conceivable by those skilled in the art and components substantially identical therewith. Furthermore, the components described below can be appropriately combined. What is disclosed herein is given by way of example only, and appropriate modifications made without departing from the spirit of the disclosure and easily conceivable by those skilled in the art naturally fall within the scope of the present disclosure. To simplify the explanation, the drawings may possibly illustrate the width, the thickness, the shape, and other elements of each unit more schematically than the actual aspect. These elements, however, are given by way of example only and are not intended to limit interpretation of the present disclosure. In the present specification and the figures, components similar to those previously described with reference to previous figures are denoted by the same reference numerals, and detailed explanation thereof may be appropriately omitted.

When the term “on” is used to describe an aspect where a first structure is disposed on a second structure in the present specification and the claims, it includes both of the following cases unless otherwise noted: a case where the first structure is disposed directly on and in contact with the second structure, and a case where the first structure is disposed on the upper side of the second structure with another structure interposed therebetween.

### First Embodiment

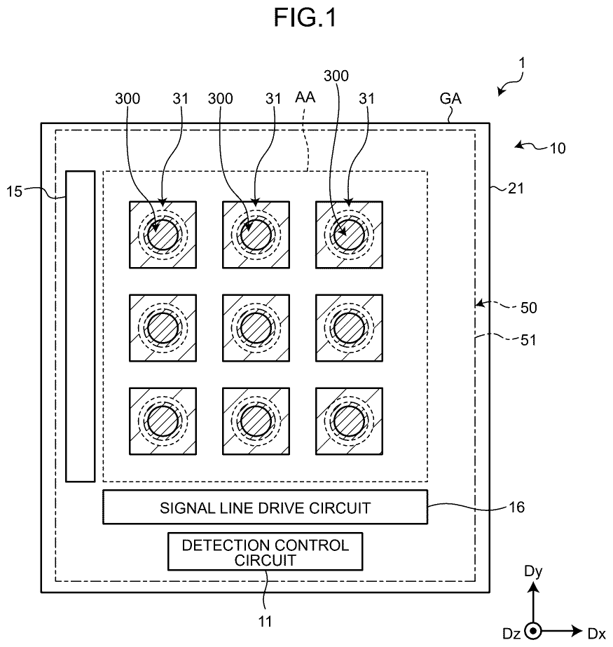

FIG. 1 is a plan view of a fluorescence detection device according to a first embodiment. As illustrated in FIG. 1, a fluorescence detection device 1 includes a sensor part 10 and a detector 50. The detector 50 includes a plurality of light-receiving elements 31 and a plurality of housing parts 300 on a substrate 21. The housing parts 300 are arranged in a matrix (row-column configuration), for example. The housing part 300 is a holding part for holding a sample. The detector 50 includes a light guide layer 51. The light-receiving elements 31 provided inside the light guide layer 51 are arranged in a grid pattern surrounding the housing parts 300 in plan view.

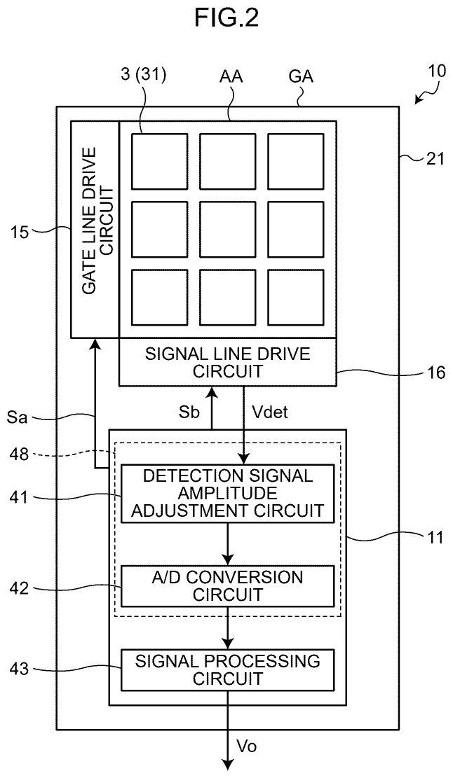

FIG. 2 is a block diagram of an exemplary configuration of the fluorescence detection device according to the first embodiment. As illustrated in FIG. 2, the sensor part 10 includes the substrate 21, and a plurality of sensor pixels 3 (light-receiving elements 31), a gate line drive circuit 15, a signal line drive circuit 16, and a detection control circuit 11 provided on the substrate 21.

The substrate 21 has a detection region AA and a peripheral region GA. The detection region AA is a region provided with the sensor pixels 3. Each sensor pixel 3 is an optical sensor including the light-receiving element 31 and the housing part 300, and also includes a capacitive element Ca and a drive transistor Tr, which will be described later. The peripheral region GA is a region between the outer periphery of the detection region AA and the outer end of the substrate 21, where the sensor pixels 3 are not provided. The gate line drive circuit 15, the signal line drive circuit 16, and the detection control circuit 11 are provided in the peripheral region GA. The substrate 21 is a drive circuit substrate that drives a sensor for each predetermined detection region and is also called a backplane or active matrix substrate.

In the following description, a first direction Dx is one direction in a plane parallel to the substrate 21. A second direction Dy is one direction in the plane parallel to the substrate 21 and is orthogonal to the first direction Dx. The second direction Dy may intersect the first direction Dx without being orthogonal thereto. A third direction Dz is a direction orthogonal to the first direction Dx and the second direction Dy and is a normal direction to the main surface of the substrate 21. The term “plan view” refers to the positional relation when viewed from a direction perpendicular to the substrate 21.

The sensor pixels 3 have the function of outputting electrical signals corresponding to light incident on their respective light-receiving element 31. The sensor pixel 3 can detect the intensity of fluorescence generated in the housing part 300 via a detection circuit 48, which will be described later, or other components. The light-receiving element 31 is a photoelectric conversion element and is, for example, an organic photodiode (OPD) with an organic semiconductor or a positive intrinsic negative (PIN) photodiode. The sensor pixels 3 (light-receiving elements 31) are arranged in a matrix (row-column configuration) in the detection region AA of the substrate 21.

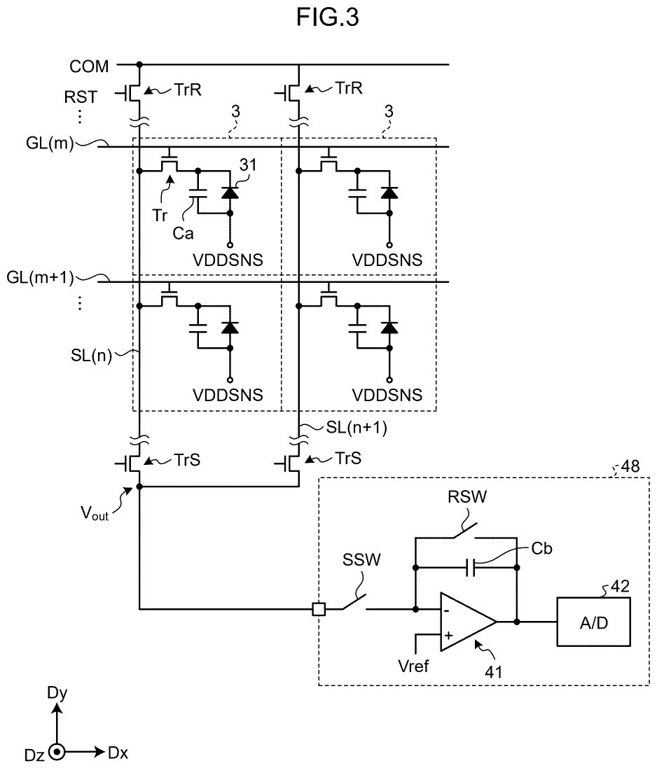

The detection control circuit 11 is a circuit that supplies control signals Sa and Sb (refer to FIG. 2) to the gate line drive circuit 15 and the signal line drive circuit 16, respectively, and supplies reset signals RST (not illustrated in FIG. 2, and refer to FIG. 3) to reset transistors TrR, for example, thereby controlling the operations of these components. The gate line drive circuit 15 outputs gate drive signals to gate lines GL (refer to FIG. 3) based on the control signals Sa. The signal line drive circuit 16 electrically couples signal lines SL selected based on the control signals Sb to the detection control circuit 11.

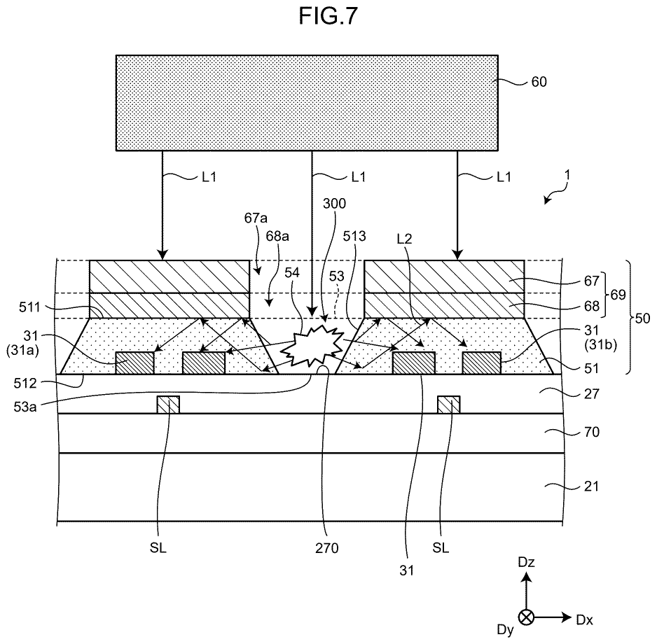

The sensor pixel 3 outputs electrical signals to the signal line drive circuit 16 as detection signals Vdet. The detection control circuit 11 performs signal processing on the detection signals Vdet from the sensor pixels 3 and outputs sensor values Vo based on the detection signals Vdet to a host IC (not illustrated). Thus, the fluorescence detection device 1 detects information on a sample 54 (refer to FIG. 7).

As illustrated in FIG. 2, the detection control circuit 11 includes a detection signal amplitude adjustment circuit 41, an A/D conversion circuit 42, and a signal processing circuit 43. The detection signal amplitude adjustment circuit 41 and the A/D conversion circuit 42 included in the detection control circuit 11 serve as the detection circuit 48 coupled to the signal lines SL (refer to FIG. 3) and configured to perform signal processing on the detection signals Vdet.

Next, an exemplary configuration of the sensor part 10 is described. FIG. 3 is a circuit diagram of the sensor pixels according to the first embodiment. As illustrated in FIG. 3, the capacitive element Ca is a capacitance (sensor capacitance) formed in the light-receiving element 31 and is coupled in parallel with the light-receiving element 31.

FIG. 3 illustrates two gate lines GL(m) and GL(m+1) arrayed in the second direction Dy out of the gate lines GL. FIG. 3 also illustrates two signal lines SL(n) and SL(n+1) arrayed in the first direction Dx out of the signal lines SL. The sensor pixel 3 corresponds to the region surrounded by the gate lines GL and the signal lines SL.

The drive transistors Tr are provided corresponding to the respective light-receiving elements 31. The drive transistor Tr is composed of a thin-film transistor (TFT) and is an n-channel metal oxide semiconductor (MOS) TFT in this example.

Each of the gate lines GL is coupled to the gates of the drive transistors Tr arrayed in the first direction Dx. Each of the signal lines SL is coupled to one of the source and the drain of each of the drive transistors Tr arrayed in the second direction Dy. The other of the sources and the drains of each of the drive transistors Tr is coupled to the cathode of the light-receiving element 31 and the capacitive element Ca.

The anode of the light-receiving element 31 is supplied with a sensor power supply signal VDDSNS from a power supply circuit (not illustrated). The signal line SL and the capacitive element Ca are supplied with a sensor reference voltage COM, which is the initial potential of the signal line SL and the capacitive element Ca, from the power supply circuit via the reset transistor TrR.

When light is incident on the sensor pixel 3 in an exposure period, a current corresponding to the amount of light flows through the light-receiving element 31, thereby accumulating electric charge in the capacitive element Ca. When the drive transistor Tr is turned on in a readout period, a current flows through the signal line SL corresponding to the electric charge accumulated in the capacitive element Ca. The signal line SL is coupled to the detection circuit 48 via an output transistor TrS of the signal line drive circuit 16. With this configuration, the fluorescence detection device 1 can detect signals corresponding to the amount of light incident on the light-receiving element 31 for each sensor pixel 3.

In the readout period, a switch SSW is turned on, and the detection circuit 48 is coupled to the signal line SL. The detection signal amplitude adjustment circuit 41 of the detection circuit 48 converts the detection signals into a voltage corresponding to the current or the electric charge supplied from the signal line SL. A non-inverting input terminal (+) of the detection signal amplitude adjustment circuit 41 receives a reference potential (Vref) with a fixed potential, and an inverting input terminal (−) is coupled to the signal line SL. The reference potential (Vref) voltage according to the present embodiment is the same signal as the sensor reference voltage COM. The detection signal amplitude adjustment circuit 41 includes a capacitive element Cb and a reset switch RSW. In a reset period, the reset switch RSW is turned on, and the electric charge of the capacitive element Cb is reset.

As described above, the detection signal amplitude adjustment circuit 41 illustrated in FIGS. 2 and 3 is a circuit that adjusts the amplitude of the detection signals Vdet output from the sensor pixels 3 and is composed of, for example, an amplifier.

As illustrated in FIGS. 2 and 3, the A/D conversion circuit 42 converts the analog signals output from the detection signal amplitude adjustment circuit 41 into digital signals. As illustrated in FIG. 2, the signal processing circuit 43 performs signal processing on the digital signals from the A/D conversion circuit 42 and transmits the sensor value Vo to the host IC (not illustrated). Thus, the signal processing circuit 43 is a circuit that performs signal processing on the detection signals Vdet from the light-receiving elements 31.

The drive transistor Tr is not limited to an n-type TFT and may be a p-type TFT. The pixel circuit of the sensor pixel 3 illustrated in FIG. 3 is given by way of example only, and the sensor pixel 3 may include a plurality of transistors corresponding to one light-receiving element 31.

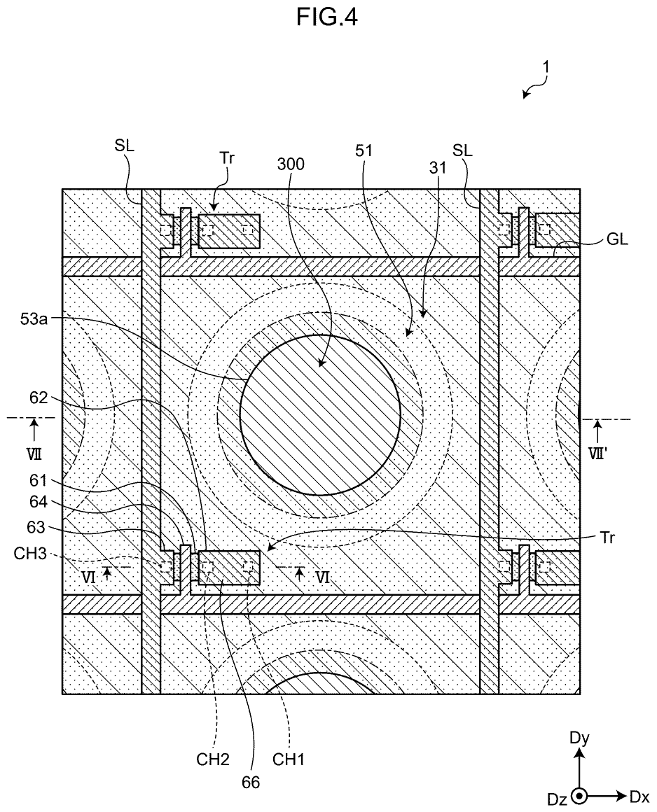

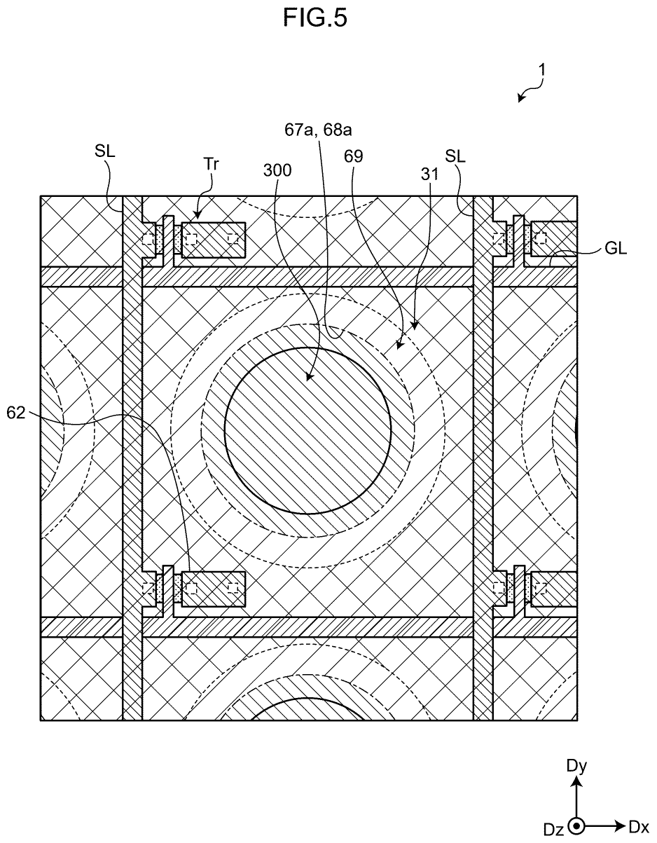

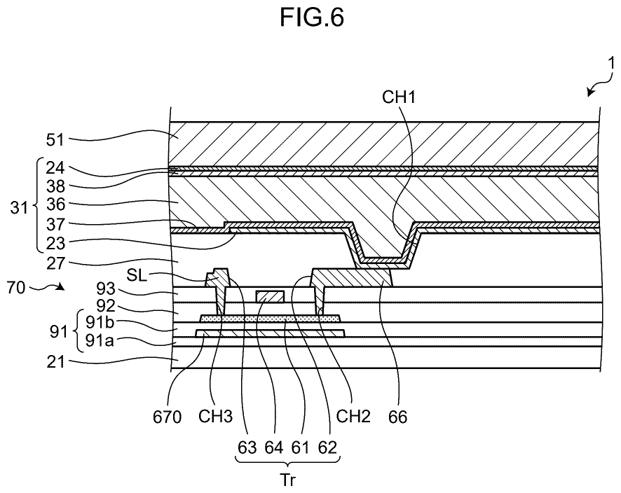

FIG. 4 is a plan view of a light guide layer of the fluorescence detection device according to the first embodiment. FIG. 5 is a plan view of a light-reducing layer of the fluorescence detection device according to the first embodiment. FIG. 6 is a sectional view along line VI-VI′ of FIG. 4. FIG. 7 is a sectional view along line VII-VII′ of FIG. 4.

As indicated by the dot-hatched area in FIG. 4 and illustrated in FIG. 7, the light guide layer 51 is a light-transmitting layer provided on an insulating film 27 to cover the light-receiving element 31 and efficiently guide fluorescence L2. A through-hole 53 extending from a first surface 511 to a second surface 512 of the light guide layer 51 serves as the housing part 300. The housing part 300 has an opening bottom 53a of the through-hole 53 on the second surface 512. As illustrated in FIGS. 4 and 7, a sidewall 513 of the housing part 300 tapers toward the insulating film 27. As illustrated in FIG. 4, one housing part 300 is provided at a position surrounded by the gate lines GL and the signal lines SL. The housing part 300 has a circular shape in plan view. The shape of the housing part 300 is not particularly limited and may be square or polygonal in plan view.

As illustrated in FIG. 4, one light-receiving element 31 is disposed surrounding one housing part 300. As illustrated in FIG. 5, a light-reducing layer 69 is provided on the light guide layer 51 in the third direction Dz and disposed at a position overlapping the light-receiving element 31 in plan view. The light-reducing layer 69 will be described later in detail with reference to FIG. 7. For convenience of explanation, with respect to the light-receiving element 31 surrounding one housing part 300 illustrated in FIG. 7, the light-receiving elements 31 surrounding the housing parts 300 adjacent to the one housing part 300 may be referred to as light-receiving elements 31a and 31b.

The drive transistor Tr illustrated in FIG. 4 includes a semiconductor layer 61, a source electrode 62, a drain electrode 63, and a gate electrode 64. The semiconductor layer 61 extends along the gate line GL and intersects the gate electrode 64 in plan view. The gate electrode 64 is coupled to the gate line GL and extends in a direction orthogonal to the gate line GL (second direction Dy).

One end of the semiconductor layer 61 is coupled to the source electrode 62 via a contact hole CH2. The source electrode 62 is coupled to a coupling pad 66 and is extended to the center of a lower electrode 23 (refer to FIG. 6) of the light-receiving element 31. The lower electrode 23 is coupled to the coupling pad 66 at the center via a contact hole CH1. With this configuration, the source electrode 62 of the drive transistor Tr is electrically coupled to the light-receiving element 31. The other end of the semiconductor layer 61 is coupled to the drain electrode 63 via a contact hole CH3. The drain electrode 63 is coupled to the signal line SL.

As illustrated in FIG. 6, the fluorescence detection device 1 includes a circuit formation layer 70, the insulating film 27, and the light-receiving element 31 stacked in this order on the substrate 21. The substrate 21 is an insulating substrate and is a glass substrate made of, for example, quartz or alkali-free glass.

The circuit formation layer 70 is provided on the substrate 21. The insulating film 27 is provided on the circuit formation layer 70 including the drive transistor Tr and covers the signal line SL. The insulating film 27 is an organic planarization film formed of organic insulating material.

As illustrated in FIG. 6, the circuit formation layer 70 includes an undercoat film 91, a gate insulating film 92, and an interlayer insulating film 93 as insulating films.

The undercoat film 91 has a two-layer laminated structure composed of insulating films 91a and 91b, for example. The undercoat film 91 is formed of an inorganic insulating film, such as a silicon nitride film and a silicon oxide film. The configuration of the undercoat film 91 is not limited to that illustrated in FIG. 6. For example, the undercoat film 91 may be a single layer film or a multilayered film composed of three or more layers.

A light-shielding film 670 is provided on the insulating film 91a. The light-shielding film 670 is provided between the semiconductor layer 61 and the substrate 21. The light-shielding film 670 can prevent light from entering the channel region of the semiconductor layer 61 from the substrate 21 side.

The drive transistor Tr is composed of a thin-film transistor and is provided on the substrate 21. The semiconductor layer 61 is provided on the undercoat film 91. The gate insulating film 92 is provided on the undercoat film 91 to cover the semiconductor layer 61. The gate insulating film 92 is an inorganic insulating film, such as a silicon oxide film. The gate electrode 64 is provided on the gate insulating film 92.

The drive transistor Tr according to the present embodiment has a top-gate structure. The drive transistor Tr is not limited thereto and may have a bottom-gate structure or a dual-gate structure with the gate electrodes 64 on both the upper side and the lower side of the semiconductor layer 61.

The interlayer insulating film 93 is provided on the gate insulating film 92 to cover the gate electrode 64. The interlayer insulating film 93 has a multilayered structure composed of a silicon nitride film and a silicon oxide film, for example. The source electrode 62 and the drain electrode 63 are provided on the interlayer insulating film 93. The source electrode 62 is coupled to the source region of the semiconductor layer 61 via the contact hole CH2 formed in the gate insulating film 92 and the interlayer insulating film 93. The drain electrode 63 is coupled to the drain region of the semiconductor layer 61 via the contact hole CH3 formed in the gate insulating film 92 and the interlayer insulating film 93.

The contact hole CH1 is formed on the lower electrode 23 through the insulating film 27 in the thickness direction (third direction Dz). The lower electrode 23 is coupled to the coupling pad 66 at the bottom of the contact hole CH1.

The insulating film 27 is provided on the interlayer insulating film 93 to cover the source electrode 62 and the drain electrode 63 of the drive transistor Tr. The contact hole CH1 in the insulating film 27 according to the present embodiment is formed in a region overlapping the source electrode 62.

The light-receiving element 31 is provided on the insulating film 27. The light-receiving element 31 includes the lower electrode 23, a lower buffer layer 37, an active layer 36, an upper buffer layer 38, and an upper electrode 24. The light-receiving element 31 includes the lower electrode 23, the lower buffer layer 37, the active layer 36, the upper buffer layer 38, and the upper electrode 24 stacked in this order. The light-receiving element 31 is an organic photodiode (OPD) provided with an organic semiconductor as the active layer 36. The shape of the light-receiving element 31 is, for example, a shape having a rectangular outer periphery with a circular opening inside in plan view. The shape of the outer periphery of the light-receiving element 31 may be square.

The lower electrode 23 is the cathode electrode of the light-receiving element 31 and is formed of conductive material, such as indium tin oxide (ITO). The lower electrodes 23 are provided separately for the respective light-receiving elements 31. The lower buffer layer 37, the active layer 36, the upper buffer layer 38, and the upper electrode 24 are continuously provided over the plurality of light-receiving elements 31. Specifically, the lower buffer layer 37, the active layer 36, the upper buffer layer 38, and the upper electrode 24 are provided overlapping the lower electrodes 23 of the adjacent light-receiving elements 31. The lower electrode 23 is electrically coupled to the source electrode 62 at the bottom of the contact hole CH1 near the drive transistor Tr. The lower buffer layer 37, the active layer 36, the upper buffer layer 38, and the upper electrode 24 each may be divided for each sensor pixel 3.

The active layer 36 changes its characteristics (e.g., voltage-current characteristics and resistance) due to incident light. The active layer 36 is made of organic material. Specifically, the active layer 36 has a bulk heterojunction structure in which a p-type organic semiconductor and an n-type fullerene derivative ((6,6)-phenyl-C₆₁-butyric acid methyl ester) (PCBM), which is an n-type organic semiconductor, are mixed. Examples of the active layer 36 include, but are not limited to, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), derivative of perylene (PDI), etc., which are low-molecular organic materials.

The active layer 36 can be formed by vapor deposition (dry process) using these low-molecular organic materials. In this case, the active layer 36 may be, for example, a multilayered film of CuPc and F₁₆CuPc or of rubrene and C₆₀. The active layer 36 can also be formed by coating (wet process). In this case, the active layer 36 is made of a combination of the low-molecular organic material described above and high-molecular organic material. Examples of the high-molecular organic material include, but are not limited to, poly(3-hexylthiophene) (P3HT), F8-alt-benzothiadiazole (F8BT), etc. The active layer 36 may be a film made of a mixture of P3HT and PCBM or a mixture of F8BT and PDI.

The lower buffer layer 37 is an electron transport layer, and the upper buffer layer 38 is a hole transport layer. The lower buffer layer 37 and the upper buffer layer 38 are provided to facilitate the electrons and holes generated in the active layer 36 reaching the lower electrode 23 or the upper electrode 24. The lower buffer layer 37 (electron transport layer) is provided directly on the lower electrode 23. The active layer 36 is provided directly on the lower buffer layer 37. The electron transport layer is made of ethoxylated polyethyleneimine (PEIE) or the like.

The upper buffer layer 38 (hole transport layer) is provided directly on the active layer 36, and the upper electrode 24 is provided directly on the upper buffer layer 38. The hole transport layer is made of a metal oxide layer. Examples of the material of the metal oxide layer include, but are not limited to, tungsten oxide (WO₃), molybdenum oxide (MoO₃), etc.

The materials and manufacturing methods for the lower buffer layer 37, the active layer 36, and the upper buffer layer 38 are given by way of example only, and other materials and manufacturing methods may be used. For example, the lower buffer layer 37 and the upper buffer layer 38 are not limited to a single layer film and may be formed as a multilayered film including a hole block layer and an electron block layer. The sensor pixel circuit is appropriately configured based on the orientation of the diode.

The upper electrode 24 is provided on the upper buffer layer 38. The upper electrode 24 is the anode electrode of the light-receiving element 31 and is continuously formed over the entire detection region AA. In other words, the upper electrode 24 is continuously provided on the light-receiving elements 31. The upper electrode 24 faces the lower electrodes 23 across the lower buffer layer 37, the active layer 36, and the upper buffer layer 38. The upper electrode 24 is formed of light-transmitting conductive material, such as ITO and IZO. Alternatively, the upper electrode 24 may be a thin metal film made of silver (Ag), aluminum (Al), gold (Au), or other metals having light-transmitting properties by having a thickness of the order of several tens of nanometers. The upper electrode 24 may be a multilayered film of a plurality of light-transmitting conductive materials.

Thus, the fluorescence detection device that is thin and has a relatively large area can be formed by providing the drive transistors Tr and the light-receiving elements 31 on a single substrate 21.

As illustrated in FIG. 7, the fluorescence detection device 1 includes a light source 60, the substrate 21, the circuit formation layer 70, the insulating film 27, and the detector 50. In the fluorescence detection device 1, the substrate 21, the circuit formation layer 70, the insulating film 27, and the detector 50 are stacked in this order in the third direction Dz perpendicular to the substrate 21.

When the fluorescence detection device 1 irradiates the sample 54 with excitation light L1 having a predetermined wavelength, the substance in the sample 54 is excited and emits fluorescence L2 having spectral characteristics with the peak wavelength that slightly deviates from the wavelength of the excitation light. The fluorescence detection device 1 enables observing the intensity of the fluorescence L2 and the emission intensity distribution of the fluorescence L2.

The light source 60 is a light-emitting element that oscillates and outputs predetermined excitation light L1 toward the upper surface of the detector 50.

The detector 50 includes the light guide layer 51, the through-holes 53, and the light-receiving elements 31. The light guide layer 51 is a light-transmitting layer having the first surface 511 and the second surface 512 opposite to the first surface 511. The through-hole 53 extends from the first surface 511 to the second surface 512. The light-receiving element 31 is covered by the light guide layer 51 and receives the fluorescence L2 emitted from the sample 54 due to the excitation light L1.

The light guide layer 51 illustrated in FIG. 7 is formed of an inorganic insulating film, such as a silicon nitride film (SiN) or a silicon oxynitride film (SiON). The light guide layer 51 may be made of light-transmitting organic material, such as acrylic resin.

The light guide layer 51 preferably has a higher refractive index than the substrate 21 and a fluorescent solution and has high transmittance for the fluorescence L2 and low transmittance for the excitation light L1.

The opening bottom 53a is covered by an upper surface 270 of the insulating film 27. The light guide layer 51 is positioned on the upper surface 270 of the insulating film 27 and is formed integrally with the insulating film 27.

The housing parts 300 that accommodate the sample 54 are arranged in such a manner that each housing part is surrounded by the sidewall 513 of the through-hole 53.

As illustrated in FIG. 7, the detector 50 includes the light-reducing layer 69. The light-reducing layer 69 is a layer that reduces the transmission of excitation light and includes a light-shielding layer 67 and a reflective layer 68. The detector 50 is composed of the light guide layer 51, the reflective layer 68, and the light-shielding layer 67 stacked in this order. The light-shielding layer 67 has a plurality of openings 67a penetrating the light-shielding layer 67 in the third direction Dz, and the reflective layer 68 has a plurality of openings 68a penetrating the reflective layer 68 in the third direction Dz. The openings 67a and 68a are formed at a position overlapping the housing part 300.

As illustrated in FIG. 5, the openings 67a and 68a have substantially the same size as the housing part 300 in plan view and have a circular shape in plan view, for example.

The light-shielding layer 67 blocks the excitation light L1 output from the light source 60, thereby reducing the transmission of the excitation light L1. The light-shielding layer 67 is formed of a black resin or a metal, such as molybdenum (Mo), having light-shielding properties against the excitation light L1 and high absorptance for the excitation light L1.

This configuration can block the excitation light L1 incident on the light-shielding layer 67 and prevent the excitation light L1 from reaching the light-receiving element 31.

The reflective layer 68 reflects the excitation light L1 output from the light source 60, thereby reducing the transmission of the excitation light L1. The reflective layer 68 is formed of a resin or a metal having high reflectance for the fluorescence L2.

This configuration can reflect the fluorescence L2 and causes it to propagate through the light guide layer 51 and be incident on the light-receiving element 31.

The housing part 300 and the openings 67a and 68a are filled with a specimen, and the sample 54 is accommodated in the housing part 300.

The specimen is, for example, a fluorescent solution obtained by staining a sample with a fluorescent dye and dispersing it in a liquid or dissolving it in a solvent. The fluorescent dye and the solvent may be appropriately selected and used for the object to be analyzed and are not particularly limited.

Examples of the fluorescent substances serving as the sample 54 include, but are not limited to, organic dyes (fluorescein, rhodamine, and their derivatives, Texas Red, and sulforhodamine), amino acids (tryptophan, phenylalanine, and tyrosine), base pair derivatives, chlorophyll, rare earth elements, fluorescent proteins, fluorescent probes, etc.

This configuration can separate the excitation light L1 from the fluorescence L2 without requiring a cut filter, thereby enabling the downsizing of the entire device in a simpler manner.

The light-reducing layer 69 reduces the amount of the excitation light L1 incident on the light-receiving element 31. As a result, the fluorescence L2 generated by the specimen in each housing part 300 enters the light-receiving element 31 with the excitation light L1 reduced. This configuration can improve the accuracy of detection of the fluorescence L2 generated by the specimen in each housing part 300.

Since the light guide layer 51 has light-transmitting properties, the fluorescence L2 generated by the specimen in the specific housing part 300 illustrated in FIG. 7 may possibly reach not only the light-receiving element 31 intended to receive the fluorescence but also the light-receiving elements 31a and 31b. However, the light-receiving element 31 intended to receive the fluorescence receives a larger amount of the fluorescence L2 generated in the specific housing part 300 illustrated in FIG. 7 than the adjacent light-receiving elements 31a and 31b. Therefore, the detected fluorescence intensity is highest at the light-receiving element 31 closest to and around the specific housing part 300 illustrated in FIG. 7 and is lower at the light-receiving elements 31a and 31b farther away from the housing part 300. In other words, the light-receiving element 31 is more affected by the fluorescence L2 generated in the specific housing part 300 described above and less affected by the fluorescence L2 generated in the housing parts 300 closest to the light-receiving elements 31a and 31b. By contrast, the light-receiving elements 31a and 31b are more affected by the fluorescence L2 generated in the housing part 300 closest to each of them and less affected by the fluorescence L2 generated in the specific housing part 300 described above closest to the light-receiving element 31.

Therefore, by statistically determining the intensity distribution across the plurality of light-receiving elements 31 including the light-receiving elements 31a and 31b, the in-plane fluorescence intensity distribution in the detection region AA (refer to FIG. 1) can be measured. As a result, it is possible to identify the housing parts 300 where the fluorescence intensity is high, based on the fluorescence intensity distribution.

### First Modification of the First Embodiment

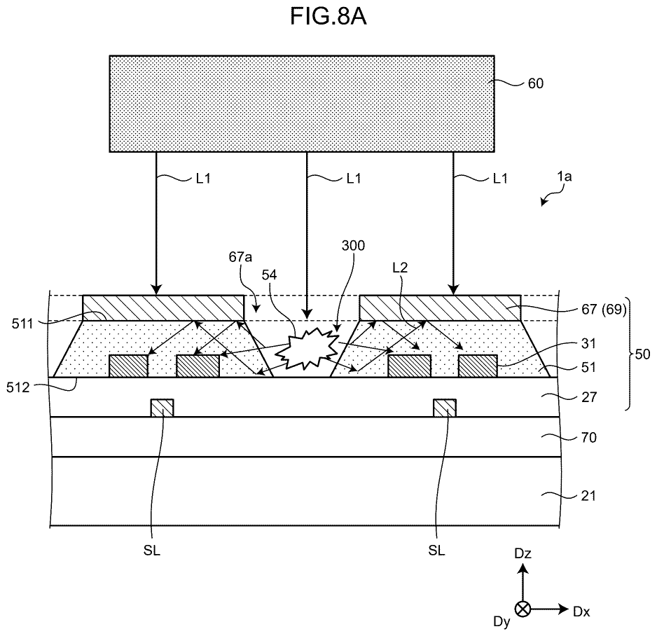

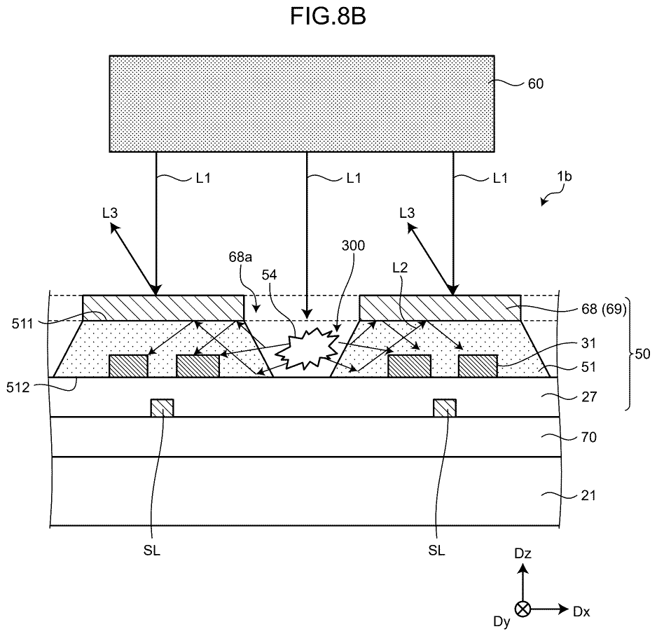

FIG. 8A is a sectional view of the fluorescence detection device according to a first modification of the first embodiment.

As illustrated in FIG. 8A, a fluorescence detection device 1a according to the first modification of the first embodiment does not necessarily include the reflective layer 68, and only the light-shielding layer 67 may be provided on the light guide layer 51. This configuration can block the excitation light L1 incident on the light-shielding layer 67 and prevent the excitation light L1 from reaching the light-receiving element 31.

### Second Modification of the First Embodiment

FIG. 8B is a sectional view of the fluorescence detection device according to a second modification of the first embodiment.

As illustrated in FIG. 8B, a fluorescence detection device 1b according to the second modification of the first embodiment does not necessarily include the light-shielding layer 67, and only the reflective layer 68 may be provided on the light guide layer 51. This configuration can reflect the excitation light L1 incident on the reflective layer 68 as reflected light L3 and prevent the excitation light L1 from reaching the light-receiving element 31.

### Second Embodiment

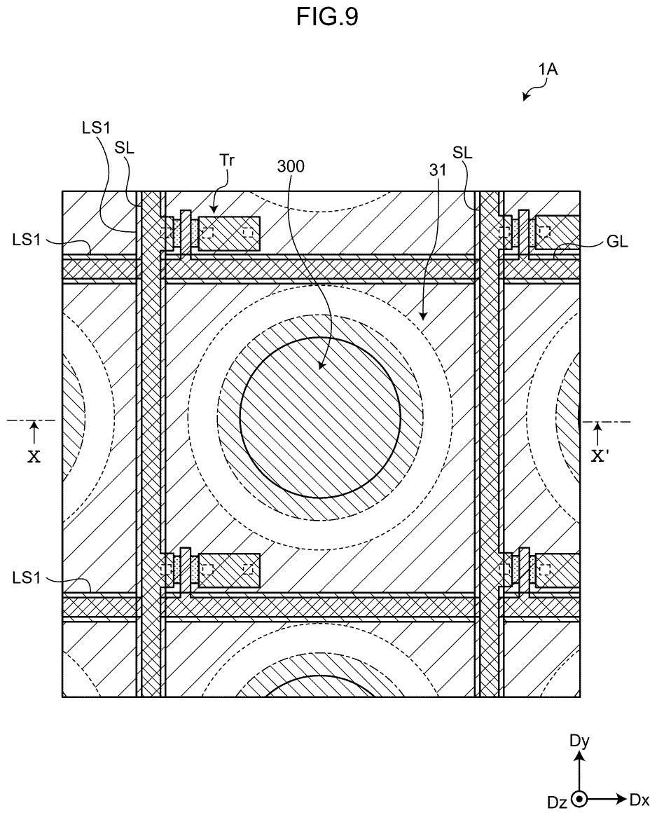

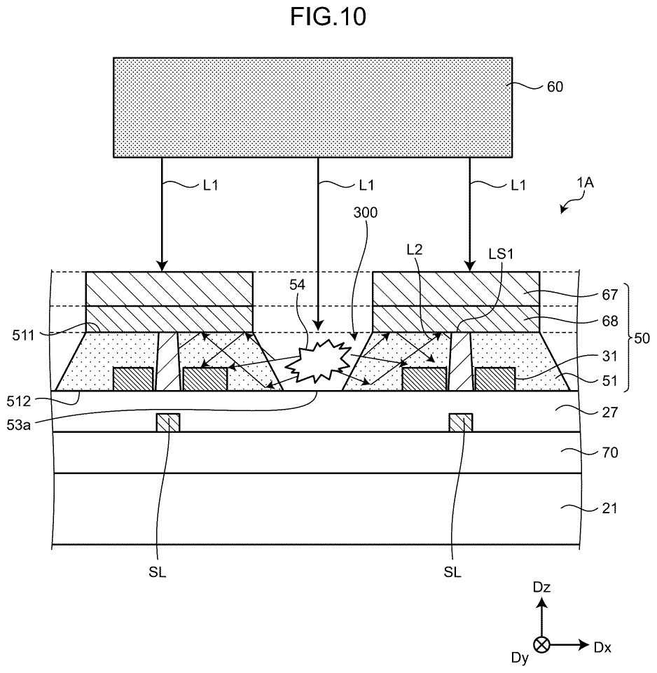

FIG. 9 is a plan view of the fluorescence detection device according to a second embodiment. FIG. 10 is a sectional view along line X-X′ of FIG. 9. In the following description, the same components as those described in the embodiment above are denoted by the same reference numerals, and duplicated explanation is omitted.

As illustrated in FIGS. 9 and 10, a fluorescence detection device 1A includes the substrate 21, the circuit formation layer 70, the insulating film 27, and the detector 50. The detector 50 further includes a light-shielding film LS1. The light-shielding film LS1 is formed of a black resin or a metal, such as molybdenum (Mo), having light-shielding properties against the fluorescence L2 and high absorptance for the fluorescence L2.

As illustrated in FIG. 9, the light-shielding film LS1 is provided at a position overlapping the gate lines GL and the signal lines SL and surrounding each of the light-receiving elements 31 in plan view. As illustrated in FIG. 10, the light-shielding film LS1 is covered by the light guide layer 51.

When each of the adjacent light-receiving elements 31 is not surrounded by the light-shielding film LS1, the fluorescence L2 emitted from the specimen in the housing part 300 adjacent to a first light-receiving element 31 may possibly be detected by a second light-receiving element 31. By contrast, when each of the light-receiving elements 31 is surrounded by the light-shielding film LS1, the fluorescence L2 emitted from the specimen in the housing part 300 adjacent to the first light-receiving element 31 is not detected by the second light-receiving element 31.

This configuration can reduce the leakage of the fluorescence L2 from the light-receiving element 31 surrounded by the light-shielding film LS1. Therefore, the present embodiment can improve the accuracy of detecting the fluorescence generated by the specimen in each housing part 300 using the light-receiving element 31.

The light-shielding film LS1 may be formed of a metal (e.g., silver (Ag) or aluminum (Al)) having light-shielding properties against the fluorescence L2 and high reflectance for the fluorescence L2. In this case, the fluorescence L2 that propagates through the light guide layer 51 and reaches the light-shielding film LS1 is reflected by the light-shielding film LS1. When the reflected light propagates through the light guide layer 51 again, part of the light is incident on the light-receiving element 31, thereby increasing the detection intensity.

### Third Embodiment

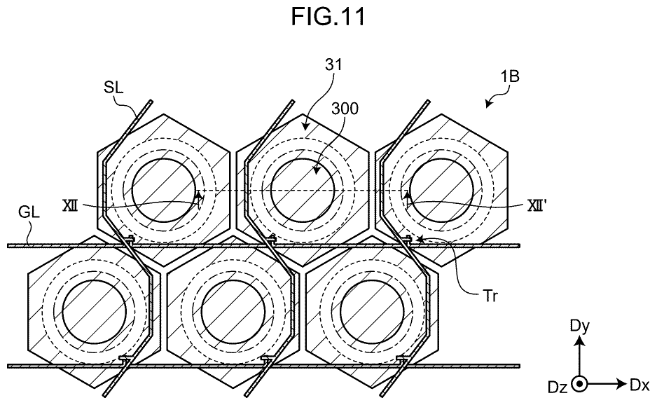

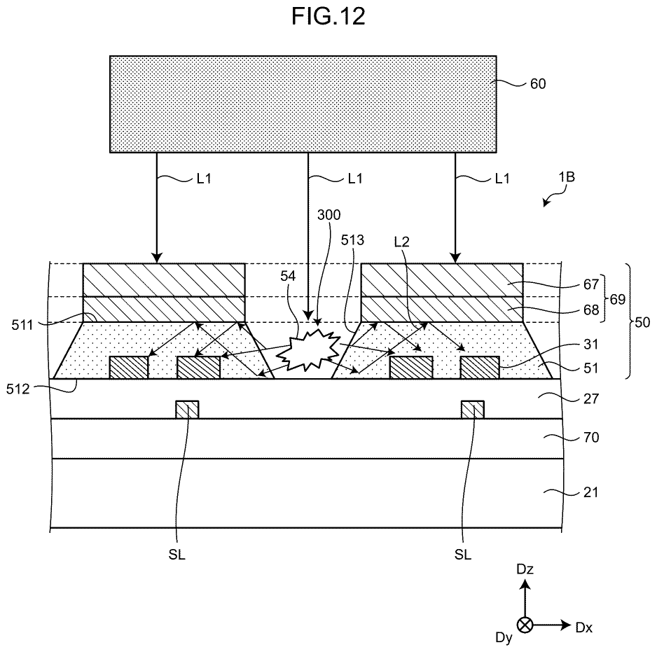

FIG. 11 is a plan view of the fluorescence detection device according to a third embodiment. FIG. 12 is a sectional view along line XII-XII′ of FIG. 11. In the following description, the same components as those described in the embodiments above are denoted by the same reference numerals, and duplicated explanation is omitted.

A fluorescence detection device 1B illustrated in FIG. 11 and FIG. 12 includes the substrate 21, the circuit formation layer 70, the insulating film 27, and the detector 50. As illustrated in FIG. 11, the external shape of the light-receiving element 31 is hexagonal in plan view.

The light-receiving element 31 illustrated in FIGS. 11 and 12 has two sides along the second direction Dy. One side is disposed at a position overlapping the signal line SL in plan view. The other side is disposed at a position not overlapping the signal line SL in plan view.

The signal line SL is bent and extends across the light-receiving elements 31 adjacent to each other in the second direction Dy in plan view.

If the signal line SL is disposed between the adjacent light-receiving elements 31 as in the first embodiment, the bending angle of the signal line SL increases, resulting in an increased length of the signal line SL. By contrast, the signal line SL according to the third embodiment is disposed overlapping the light-receiving elements 31 in plan view. As a result, the bending angle of the signal line SL is reduced, and the length of the signal line SL is reduced, thereby reducing occurrence of issues, such as signal delay.

This configuration increases the area of the light-receiving elements present at an equal distance from the housing part 300, as compared with the fluorescence detection device 1 according to the first embodiment. Therefore, the present embodiment can improve the accuracy of detecting the fluorescence generated by the specimen in each housing part 300 using the light-receiving element 31.

### Fourth Embodiment

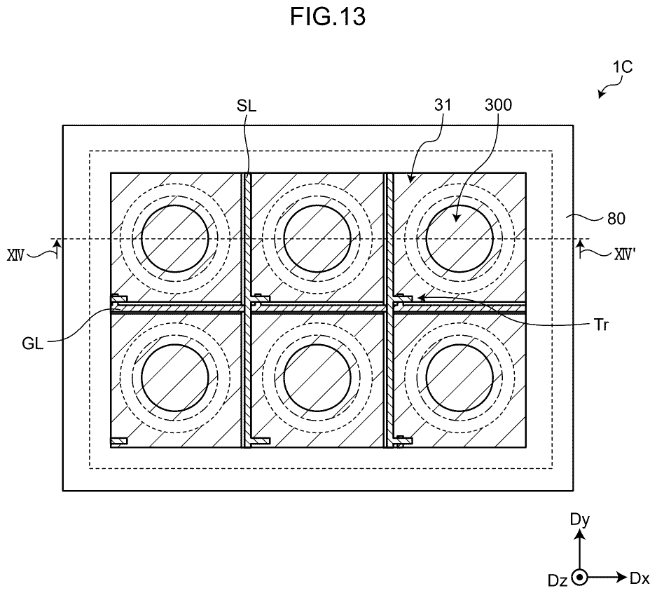

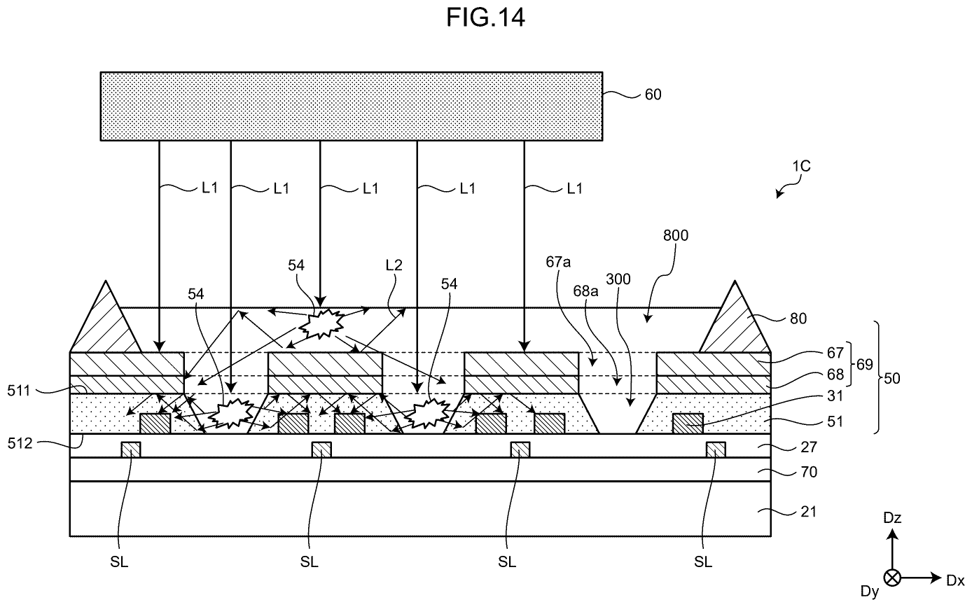

FIG. 13 is a plan view of the fluorescence detection device according to a fourth embodiment. FIG. 14 is a schematic sectional view along line XIV-XIV′ of FIG. 13. In the following description, the same components as those described in the embodiments above are denoted by the same reference numerals, and duplicated explanation is omitted.

A fluorescence detection device 1C illustrated in FIG. 13 and FIG. 14 includes the substrate 21, the circuit formation layer 70, the insulating film 27, the detector 50, and a bank 80 provided on the detector 50.

The bank 80 is disposed surrounding more than one light-receiving element 31 in plan view. The bank 80 is disposed on the light-reducing layer 69. The bank 80 is formed of acrylic resin, for example. The housing parts 300, the openings 67a and 68a, and an enclosed region 800 surrounded by the bank 80 are filled with the specimen.

The sample 54 is accommodated in the housing part 300. The sample 54 is also accommodated on the light-reducing layer 69 in the enclosed region 800.

This configuration can increase the amount of sample 54, thereby increasing the absolute value of the fluorescence intensity.

In the enclosed region 800, the fluorescence L2 emitted from the sample 54 due to the excitation light L1 is totally reflected at the interface between the air and the specimen or directly incident on the light-receiving element 31.

This configuration increases the absolute intensity of fluorescence, thereby increasing the signal-to-noise ratio (SNR) and improving the accuracy of detecting the fluorescence generated by the specimen in each housing part 300 using the light-receiving element 31.

While exemplary embodiments according to the present disclosure have been described, the embodiments are not intended to limit the present disclosure. The contents disclosed in the embodiments are given by way of example only, and various modifications can be made without departing from the spirit of the present disclosure. Appropriate modifications made without departing from the spirit of the present disclosure naturally fall within the technical scope of the present disclosure. At least one of various omissions, substitutions, and modifications of the components can be made without departing from the gist of the embodiments and modifications described above.

What is claimed is:

1. A fluorescence detection device comprising:
a substrate;
a light source configured to output excitation light to a sample; and
a detector configured to detect fluorescence, wherein
the detector comprises
a light guide layer having a first surface and a second surface opposite to the first surface and having a light-transmitting property,
a through-hole penetrating the light guide layer from the first surface to the second surface in a direction perpendicular to the substrate,
a light-receiving element covered by the light guide layer and configured to receive fluorescence emitted from the sample due to the excitation light, and
a light-reducing layer provided on the light guide layer and configured to reduce transmission of the excitation light,
the light-reducing layer has a plurality of openings,
a plurality of housing parts each surrounded by a sidewall of the through-hole and configured to accommodate the sample are formed,
the openings are formed at positions overlapping the housing parts, and
the light-receiving element is disposed surrounding each of the housing parts in plan view.

2. The fluorescence detection device according to claim 1, wherein the light-reducing layer comprises
a light-shielding layer having a light-shielding property and
a reflective layer that reflects light.

3. The fluorescence detection device according to claim 1, wherein the light-reducing layer comprises a light-shielding layer having a light-shielding property.

4. The fluorescence detection device according to claim 1, wherein the light-reducing layer comprises a reflective layer that reflects light.

5. The fluorescence detection device according to claim 2, further comprising:
a drive transistor configured to control the light-receiving element, wherein
the drive transistor is disposed on the substrate.

6. The fluorescence detection device according to claim 5, wherein
the housing parts are each surrounded by gate lines adjacent to each other and signal lines adjacent to each other,
the detector comprises a light-shielding film provided between a plurality of the light-receiving elements adjacent to each other in the light guide layer, and
the light-shielding film is disposed at a position overlapping the gate lines and the signal lines in plan view.

7. The fluorescence detection device according to claim 2, wherein the shape of the light-receiving element is hexagonal in plan view.

8. The fluorescence detection device according to claim 6, wherein the shape of the light-receiving element is hexagonal in plan view.

9. The fluorescence detection device according to claim 2, further comprising:
a bank provided on the detector, wherein
the bank is disposed so as to surround a plurality of the light-receiving elements in plan view.

10. The fluorescence detection device according to claim 5, further comprising:
a bank provided on the detector, wherein
the bank is disposed so as to surround a plurality of the light-receiving elements in plan view.
